(19) United States
(12) Patent Application Publication
(10) Pub. No.: US 2025/0166161 A1
(43) Pub. Date: May 22, 2025

(54) METHODS AND SYSTEMS FOR IMPROVING WAFER DEFECT CLASSIFICATION NUISANCE RATE

(71) Applicant: ASML Netherlands B.V., Veldhoven (NL)

(72) Inventors: Hairong LEI, San Jose, CA (US); Qian DONG, Santa Clara, CA (US); Cho Huak TEH, Los Altos, CA (US); Lingling PU, San Jose, CA (US); Chih-Yu JEN, San Jose, CA (US); Chia Wen LIN, Saratoga, CA (US)

(73) Assignee: ASML Netherlands B.V., Veldhoven (NL)

(21) Appl. No.: 18/841,032

(22) PCT Filed: Feb. 3, 2023
(86) PCT No.: PCT/EP2023/052663

§ 371 Date: Aug. 23, 2024

Related U.S. Application Data
(60) Provisional application No. 63/315,054, filed on Feb. 28, 2022.

(51) Int. Cl. G06T 7/00

(52) U.S. Cl. CPC G06T 7/0008; G06T 2207/10061; G06T 2207/20081; G06T 2207/30148

(57) ABSTRACT

An automatic defect classification method may include obtaining a set of image data comprising a set of candidate defects from an inspection tool, developing a plurality of defect review types and a plurality of nuisance review types, and classifying the set of candidate defects according to the defect review types and nuisance review types using a machine learning classifier. Using the plurality of nuisance review types in the classification method reduces a nuisance rate.

### CROSS-REFERENCE TO RELATED APPLICATIONS

This application claims priority of U.S. application 63/315,054 which was filed on 28 Feb. 2022 and which is incorporated herein in its entirety by reference.

### FIELD

The embodiments provided herein are related to a system and method for automatic defect classification, and more particularly for improving defect classification nuisance rate.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) may be employed. As the physical sizes of IC components continue to shrink, accuracy and yield in defect detection become more and more important.

Some inspection tools may generate a large number of nuisances. A nuisance may be a detection aberration or a wafer irregularity that is not considered a defect of concern. For example, a nuisance could be caused by misidentified background images or minor defects that are not consequential to the device yield of a manufacturing process. As defect review becomes increasingly critical, there is a continuing need to reduce a nuisance rate in inspection processes.

### SUMMARY

The embodiments provided herein disclose a particle beam inspection apparatus, and more particularly, an inspection apparatus using a plurality of charged particle beams.

Some embodiments of the present disclosure include a method for improving a nuisance rate in image inspection data. The method may comprise obtaining image data comprising a set of candidate defects; developing a plurality of defect review types and a plurality of nuisance review types; classifying the set of candidate defects into one or more defect types based on the plurality of defect review types during a first classification phase; classifying the set of candidate defects into a plurality of nuisance types based on the plurality of nuisance review types during the first classification phase, and applying a machine learning based multi-phase classification to the classified set of candidate defects.

Some embodiments of the present disclosure include a system for improving a nuisance rate in image inspection data, comprising: a charged particle beam apparatus including a detector; an image acquirer that includes circuitry to receive a detection signal from the detector and construct an image including a first feature; and a controller with at least one processor and a non-transitory computer readable medium comprising instructions that, when executed by the at least one processor, cause the system to: obtain image data comprising a set of candidate defects; develop a plurality of defect review types and a plurality of nuisance review types; classify the set of candidate defects into one or more defect types based on the plurality of defect review types during a first classification phase; classify the set of candidate defects into a plurality of nuisance types based on the plurality of nuisance review types during the first classification phase, and apply a machine learning based multi-phase classification to the classified set of candidate defects.

Some embodiments of the present disclosure include a non-transitory computer readable medium storing a set of instructions that is executable by one or more processors of a system to cause the system to perform a method comprising: obtaining image data comprising a set of candidate defects; developing a plurality of defect review types and a plurality of nuisance review types; classifying the set of candidate defects into one or more defect types based on the plurality of defect review types during a first classification phase; classifying the set of candidate defects into a plurality of nuisance types based on the plurality of nuisance review types during the first classification phase, and applying a machine learning based multi-phase classification to the classified set of candidate defects.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an exemplary electron beam inspection (EBI) system, consistent with embodiments of the present disclosure.

FIG. 2 is a schematic diagram illustrating an exemplary electron beam tool, consistent with embodiments of the present disclosure that can be a part of the exemplary electron beam inspection system of FIG. 1.

FIG. 3 is a block diagram illustrating an exemplary defect review system, consistent with embodiments of the present disclosure.

FIG. 4 is a schematic diagram illustrating a conventional single-phase classification tree.

FIG. 5A is a schematic diagram illustrating an exemplary case for the conventional single phase classification tree of FIG. 4.

FIG. 5B is a chart comparing the exemplary case of FIG. 5A to the results of manual review.

FIG. 5C illustrates image data of several defect types and nuisances.

FIG. 6 is a schematic diagram illustrating a multi-phase classification tree with a single nuisance bin, consistent with embodiments of the present disclosure.

FIG. 7A is a schematic diagram illustrating an exemplary case for the multi-phase classification tree of FIG. 4, consistent with embodiments of the present disclosure.

FIG. 7B is a chart comparing the exemplary case of FIG. 7A to the results of manual review, consistent with embodiments of the present disclosure.

FIG. 8 is a schematic diagram illustrating a multi-phase classification tree with multiple nuisance types, consistent with embodiments of the present disclosure.

FIG. 9A is a schematic diagram illustrating an exemplary case for the multi-phase classification tree with multiple nuisance types of FIG. 8, consistent with embodiments of the present disclosure.

FIG. 9B is a chart comparing the exemplary case of FIG. 9A to the results of manual review, consistent with embodiments of the present disclosure.

FIG. 10 is a method for improving a nuisance rate in image inspection data, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to the subject matter as recited in the appended claims. For example, although some embodiments are described in the context of utilizing electron beams, the disclosure is not so limited. Other types of charged particle beams can be similarly applied. Furthermore, other imaging systems can be used, such as optical imaging, photo detection, x-ray detection, etc.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (SCPM). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

As the physical sizes of IC components continue to shrink, accuracy and yield in defect detection become more important. Inspection images such as SEM images can be used to identify or classify a defect(s) of the manufactured ICs. To improve defect detection performance, it is important to reduce a nuisance rate in defect detection and classification. A nuisance may be a detection aberration or a wafer irregularity that is not considered a defect of concern in the inspection process. For example, a nuisance could be caused by misidentified background images or minor defects that are not consequential to the device yield of a manufacturing process. A nuisance rate may be a measure of how many nuisances are mistakenly classified as actual defects of concern during an inspection and classification process. For example, if a detection and classification process identifies 100 defects and it is later determined that 10 of those were actually misclassified nuisances, then a nuisance rate may be 10/100=10%. In some detection and classification systems, a nuisance rate may be unacceptably high.

Conventional classification schemes may use machine learning classifiers to sort inspection data into various categories, such as a nuisance category and a plurality of defect type categories. A conventional system may train a classifier using a set of training data. The conventional system may sort a large amount of nuisance data into a single nuisance category. This can cause issues in machine learning algorithms whose optimization methods are built on the assumption that data will be sorted into the different categories with somewhat equal numbers. When a real-world data set strays too far from this assumption, the classification accuracy may suffer. This issue may be called a data imbalance problem, and it may degrade classifier accuracy, causing the classifier to inadvertently classify nuisances as actual defects.

Embodiments of the disclosure may provide an automatic defect classification (ADC) system and method. The method includes acquiring a set of inspection image data from an inspection tool such as a SEM inspection tool. The image data may include, e.g., a set of defect candidates identified from SEM scans. The ADC method develops a plurality of defect review types and a plurality of nuisance review types. A machine learning (ML) classifier classifies inspection image data into bins according to the defect review types and nuisance review types. The use of plural nuisance types enables the ML classifier to better recognize nuisances and reduces the rate at which nuisances are misclassified as defects.

In some embodiments, the ADC may use multiphase classification. In the multiphase classification, the results of a first classification phase are compared to a manual review of the image data. Based on the comparison results, a set of misclassified data selected from the first phase is re-labeled correctly and put into a revised training pool for further training in another phase. Multiple iterations of this process may be performed until the training results meet expectations.

In some embodiments, a nuisance review type may be created based on a relationship or similarity to a defect review type. In some embodiments, a nuisance review type may be designed to identify data that is likely to be misclassified as a certain defect type. In some embodiments, a plurality of nuisance review types may be developed to smooth out a data imbalance problem. Such a problem can be caused by using one disproportionately large nuisance bin.

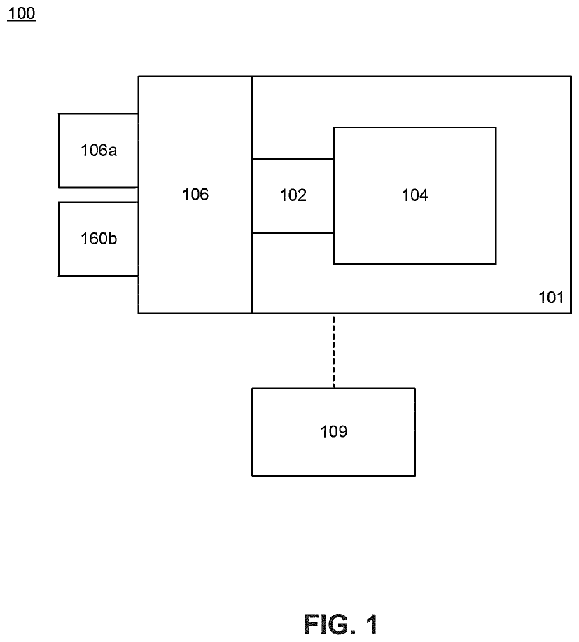

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C. Reference is now made to FIG. 1, which illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be collectively referred to as “wafers” herein). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system. A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 can part of the structure.

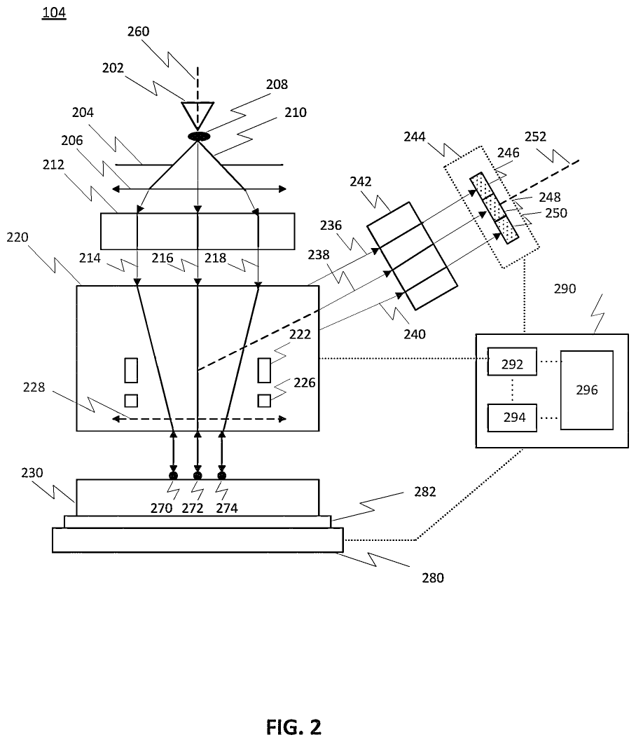

FIG. 2 illustrates a schematic diagram of an example multi-beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, an apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit. The raw image data may be processed to identify a set of defect candidates in the image data.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and SEs may be more or fewer (or even the same) than the injected electrons of primary charged-particle beam 210.

The images generated by SEM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SEM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

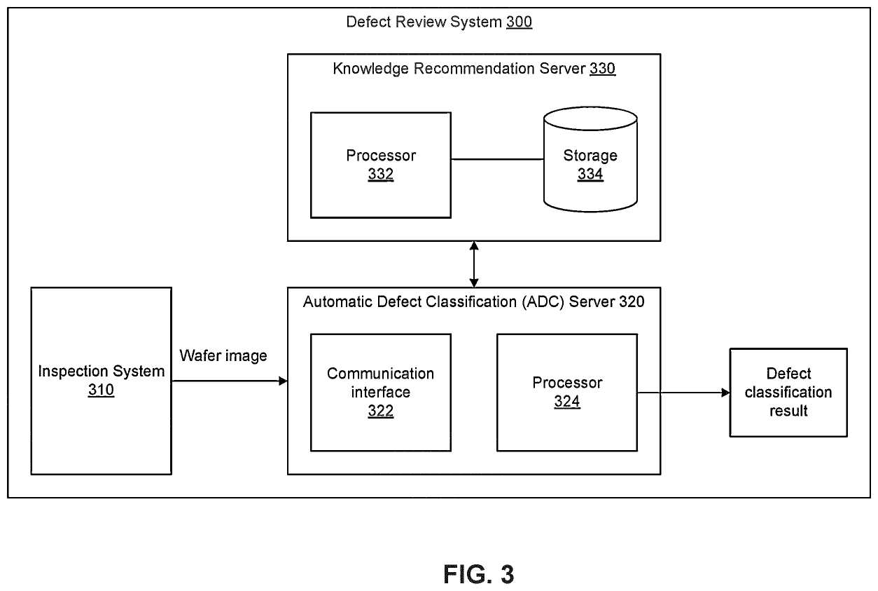

In some embodiments, a computer system may be provided that can identify defects in a wafer image and classify the defects into categories according to the defect type. For example, once a wafer image is acquired, it may be transmitted to the computer system for processing. FIG. 3 is a schematic diagram of a defect review system 300, consistent with embodiments of the present disclosure.

Referring to FIG. 3, defect review system 300 may include a wafer inspection system 310, an Automatic Defect Classification (ADC) server 320, and a knowledge recommendation server 330 electrically coupled to the ADC server 320. Wafer inspection system 310 may be EBI system 100 described with respect to FIG. 1. It is appreciated that ADC server 320 and knowledge recommendation server 330 can be part of or remote from EBI system 100.

Wafer inspection system 310 may be any inspection system that generates an inspection image of a wafer. The wafer may be a semiconductor wafer substrate, or a semiconductor wafer substrate having one or more epi-layers or process films, for example. Wafer inspection system 310 may be any currently available or developing wafer inspection system. The embodiments of the present disclosure do not limit the specific type for wafer inspection system 310. Such a system may generate a wafer image having a resolution so as to observe key features on the wafer (e.g., less than 20 nm).

ADC server 320 may include a communication interface 322 that is electrically coupled to the wafer inspection system 310 to receive the wafer image. ADC server 320 may also include a processor 324 that is configured to analyze the wafer image and detect and classify defects that appear on the wafer image and may use a defect knowledge file in this analysis, detection, or classification. The defect knowledge file may be manually provided to ADC server 320 by an operator. Alternatively, according to some embodiments of the present disclosure, the defect knowledge file may be automatically provided to ADC server 320 by knowledge recommendation server 330.

For example, knowledge recommendation server 330 may be electrically coupled to the ADC server 320. Knowledge recommendation server 330 may include a processor 332 and a storage 334. Processor 332 may be configured to build a plurality of defect knowledge files and to store the plurality of defect knowledge files in storage 334. The plurality of defect knowledge files may contain information related to various types of defects generated during various stages of wafer manufacturing processes. The various stages of wafer manufacturing processes may include, but are not limited to, a lithography process, an etching process, a chemical mechanical polishing (CMP) process, or an interconnection forming process.

Processor 332 may be configured to build the plurality of defect knowledge files based on a plurality of defect patch images. The plurality of defect patch images may be generated by a wafer inspection tool, such as electron beam tool 104 illustrated in FIG. 2. A defect patch image may be a small image (e.g., 34×34 pixels) of a portion of the wafer that contains a defect. The defect patch image may be centered on the defect, and may include neighboring pixels of the defect.

Processor 332 may be trained, via a machine learning process, to build a knowledge file related to a specific type of defect based on a plurality of defect patch images of that type of defect. For example, processor 332 may be trained to build a knowledge file related to broken line defects generated in an interconnect forming process based on a plurality of defect patch images of broken line defects.

Processor 332 may also be configured to, in response to a request for knowledge recommendation from ADC server 320, search for a knowledge file that matches a wafer image included in the received request and provide the knowledge file to the ADC server 320.

Storage 334 may store an ADC data center that contains a plurality of defect knowledge files related to various types of defects generated during various stages of wafer manufacturing processes. The plurality of defect knowledge files in the ADC data center may be built by processor 332 of knowledge recommendation server 330. Alternatively, a portion of the defect knowledge files in storage 334 may be preset by a user or an external computer system and may be preloaded into storage 334.

A defect knowledge file may include general information about a single type of defect. The general information may include patch images and feature parameters to be used for later classification (e.g., size, edge roughness, depth, height, etc.) of the single type of defect. Alternatively, according to some embodiments of the present disclosure, a defect knowledge file may include general information about a plurality of types of defects that are present in the same process layer of a wafer. The single process layer may be, for example, a substrate layer, an epitaxial layer, a thin film layer, a photoresist layer, an oxide layer, a metal interconnection layer, etc.

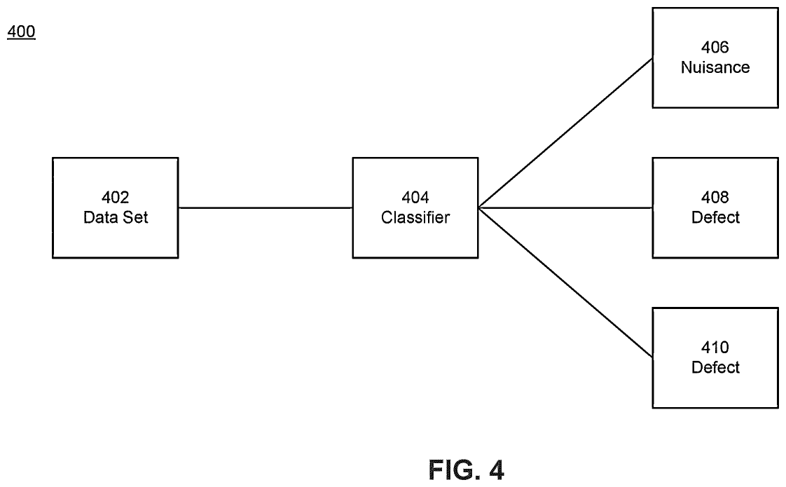

Reference is now made to FIG. 4, which is a schematic diagram illustrating a conventional classification tree 400 with one-phase ADC training. Classification tree includes an image data set 402, a classifier 404, a nuisance bin 406, and defect bins 408 and 410. Scanning one or more samples with an inspection tool such as a SEM may yield image data set 402. Image data set 402 contains a large number of candidate defect images. Candidates are potential defects on a sample surface which may be sorted by classifier 404 into bins 406, 408 and 410. Classifier 404 may classify data using an automatic defect classification system such as, e.g., ADC server 320 and knowledge recommendation server 330 of defect review system 300 in FIG. 3. As discussed above, bin 406 corresponds to nuisances, whereas bins 408 and 410 correspond to two distinct defect types. Each candidate may be identified as a defect type by comparison to a plurality of parameters according to a knowledge file for the defect type stored in storage 334. Parameters may include, e.g., size, edge roughness, depth, height, or any measurable feature parameter. Processor 324 may identify a candidate as a specific defect type according to the knowledge file and sort it into the appropriate bin. For example, processor 324 may identify image data as a match for a defect type corresponding to bin 408 and sort the candidate into bin 408. Candidates that do not sufficiently match the parameters of a real defect may be classified as nuisances. Defects and nuisances can broadly be distinguished by their expected impact on yield and device functionality. For instance, a processing imperfection, contaminant, or other measurable property may be categorized as a nuisance if it is determined not to impact yield or device functionality. A processing imperfection, contaminant, or other measurable property may be considered a defect if it poses a potential threat to yield or device functionality. In FIG. 4, while only two defect bins 408 and 410 are shown, it is appreciated that more defect bins may be used. For example, the first defect type of bin 408 could be a “hole missing” defect and the second defect type of bin 410 could be a “hole bridge” defect. Other defect types are possible, and the number of types is not limited to two. By filtering out the nuisances and binning the real defects according to their types, appropriate adjustments can be made to the manufacturing process to improve device yield and accuracy.

Classifier 404 may be a machine learning classifier. Both unsupervised machine learning and supervised machine learning models may be used to predict one or more defects. Without limiting the scope of the claims, applications of supervised machine learning algorithms are described below.

Supervised learning is the machine learning task of inferring a function from labeled training data. The training data is a set of training examples. In supervised learning, each example is a pair consisting of an input object (typically a vector) and a desired output value (also called the supervisory signal). A supervised learning algorithm analyzes the training data and produces an inferred function, which can be used for mapping new examples. An optimal scenario will allow the algorithm to correctly determine the class labels for unseen instances. This requires the learning algorithm to generalize from the training data to unseen situations in a “reasonable” way (see inductive bias).

Given a set of N training examples of the form {(x1, y1), (x2, y2), . . . , (xN, yN)} such that xi is the feature vector of the i-th example and yi is its label (e.g., class), a learning algorithm seeks a function g: X→Y, where X is the input space and Y is the output space. A feature vector is an n-dimensional vector of numerical features that represent some object. Many algorithms in machine learning require a numerical representation of objects, since such representations facilitate processing and statistical analysis. When representing images, the feature values might correspond to the pixels of an image, when representing text perhaps term occurrence frequencies. The vector space associated with these vectors is often called the feature space. The function g is an element of some space of possible functions G, usually called the hypothesis space. It is sometimes convenient to represent function g using a scoring function f: X×Y→R such that function g is defined as returning the y value that gives the highest score: g(x)=arg maxyf(x, y). Let F denote the space of scoring functions.

Although G and F can be any space of functions, many learning algorithms are probabilistic models where g takes the form of a conditional probability model g(x)=P(y|x), or f takes the form of a joint probability model f(x, y)=P(x, y). For example, naive Bayes and linear discriminant analysis are joint probability models, whereas logistic regression is a conditional probability model.

There are two basic approaches to choosing for g: empirical risk minimization and structural risk minimization. Empirical risk minimization seeks the function that best fits the training data. Structural risk minimization includes a penalty function that controls the bias/variance tradeoff.

In both cases, it is assumed that the training set contains a sample of independent and identically distributed pairs, (xi, yi). In order to measure how well a function fits the training data, a loss function L: Y×Y→R≥0 can be defined. For training example (xi, yi), the loss of predicting the value ŷ is L(yi, ŷ).

The risk R(g) of function g is defined as the expected loss of g. This can be estimated from the training data as Remp(g)=1/NΣiL(yi, g(xi))

Exemplary models of supervised learning include decision trees, ensembles (bagging, boosting, random forest), k-NN, linear regression, naive Bayes, neural networks, logistic regression, perceptron, support vector machine (SVM), relevance vector machine (RVM), and/or deep learning. In some embodiments, the classifier is a Classifier 4 (C4) type used in the e-Manager® ADC system from HMI, Inc. C4 includes a set of decision trees, constructed by selecting a subset of features randomly selected during tree construction. Classification is done by majority voting of the decision trees under a chosen number of trees in the forest and number of variables randomly selected. The above machine learning examples are not meant to be limiting, and that other machine learning algorithms are possible within the scope of the present disclosure.

To evaluate result accuracy of a classification tree, a set of SEM image data may be subjected both to the classification and to a manual review. The manual review is a more rigorous and labor-intensive analysis to determine with higher confidence the actual nature of each candidate in the set. An operator can then compare the binning of each candidate under ADC to the actual result as determined by review. For example, with reference to FIG. 4, one can determine how many candidates were binned to a first defect type bin 408 when they should have been categorized in a nuisance bin 406.

The results of the manual review may be compared to the classification results to determine performance metrics such as a nuisance rate NR. A nuisance rate NR can be a measure of “false positives,” that is, the percentage of candidates that were labeled as defects under ADC but determined to be nuisances under review. Dividing the number of false positives by the number of total positives gives a nuisance rate NR. These results are illustrated below.

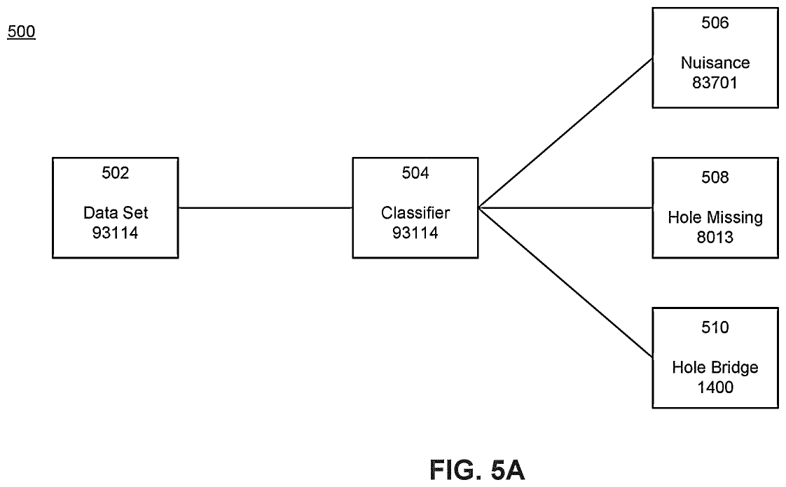

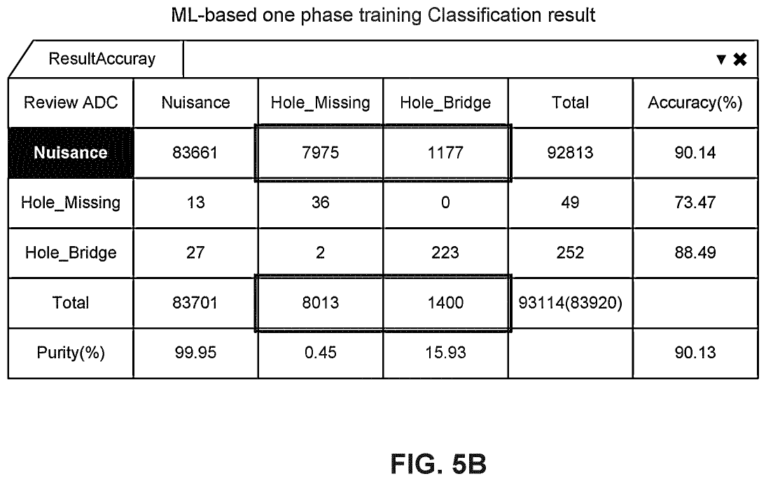

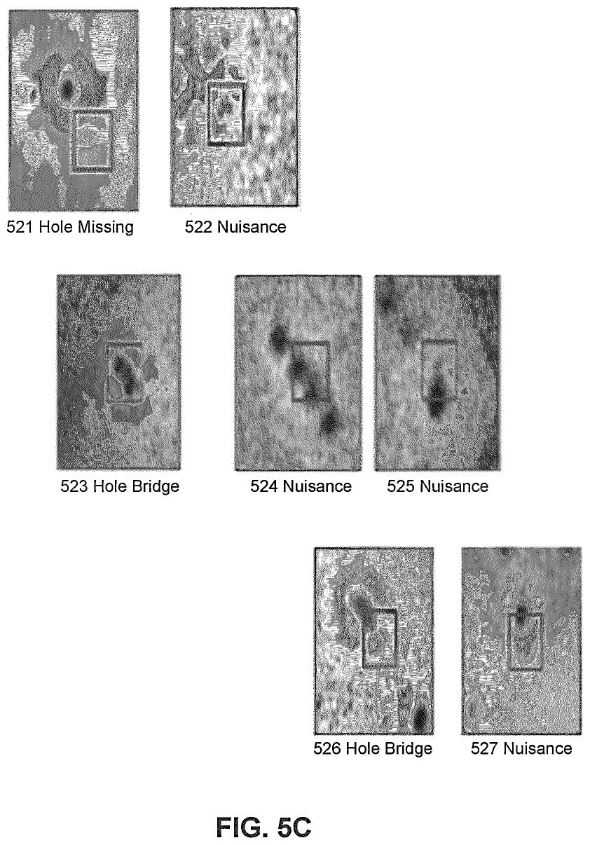

FIG. 5A depicts one example case of a conventional ADC classification tree 500 with one-phase training. The numerical values given in the example of FIG. 5A and subsequent figures are presented for illustrative purposes, and are not meant to be construed as limiting the scope of the invention. A data set 502 containing 93,114 candidates is fed to a classifier 504. For example, classifier 504 may be a C4 type classifier. Classifier 504 bins each candidate into one of three categories: nuisances 506; hole missing defect types 508; and hole bridge defect types 510. As seen in FIG. 5A, the count for each defect type is in the thousands under the single-phase classification 500.

FIG. 5B depicts a result accuracy table for the classification tree of FIG. 5A. The result accuracy table is a matrix created by comparing the ADC classification results to a manual review of the same data set 502. The columns represent binning results according to the ADC process, while the rows show more accurate results according to a rigorous manual review. The total results of each process are given in the columns/rows labeled “Total,” while cross-comparisons are given in the other matrix cells. For instance, the vertical Hole_Missing column shows that a total of 8013 candidates were identified as Hole_Missing type defects by ADC classifier 504. But using manual review, it was shown that only 36 of those candidates actually were Hole_Missing defects. Another 2 candidates were Hole_Bridge defects that were misidentified as Hole_Missing, and 7975 were actually nuisances. Similarly, the horizontal Hole_Missing row shows that manual review identified a total of 49 candidates as Hole_Missing defects. ADC had properly identified 36 of those candidates, misidentified another 13 as nuisances, and misidentified none as Hole_Bridge.

Two rectangular boxes in FIG. 5B highlight the data utilized in a nuisance rate calculation. The upper rectangular box shows the number of nuisances that were misidentified as a defect by ADC classifier 504:7975 nuisances were classified as Hole_Missing defects, and 1177 nuisances were classified as Hole_Bridge defects. The lower rectangular box shows the total number of candidates that were classified as defects: 8013 as Hole_Missing and 1400 as Hole_Bridge. Under some calculations, a nuisance rate NR may be a ratio of the number of nuisances that were misclassified as defects (as determined after review) to the total number of candidates that were classified as defects. Classification tree 500 of FIG. 5A gives a nuisance rate of:

$$NR = ( 7975 + 1177 ) / ( 8013 + 1400 ) = 97 \%$$

This nuisance rate is unacceptably high, showing that classifier 504 fails to sufficiently filter out unwanted candidates. Other nuisance rate calculations may be employed using the information in FIG. 5B. For example, the exemplary nuisance rate calculation does not directly capture the number of real defects that were misclassified as nuisances by the ADC classifier 504.

FIG. 5C shows one problem with the single-phase classification tree that leads to a high nuisance rate. Many nuisances are not easily distinguishable because their measurable characteristics approach those of real defects. Therefore, some nuisances are difficult to discern from real defects and are often binned as such. FIG. 5C shows examples of hole missing and hole bridge defects alongside nuisances that may be mistaken for them. Nuisance 522 can be mistaken for a hole missing defect 521. Nuisances 524 and 525 can be mistaken for hole bridge defect 523. Nuisance 527 can be mistaken for hole bridge defect 526. These misclassifications have a negative impact on the nuisance rate NR, and they deteriorate the performance and reliability of the defect inspection process.

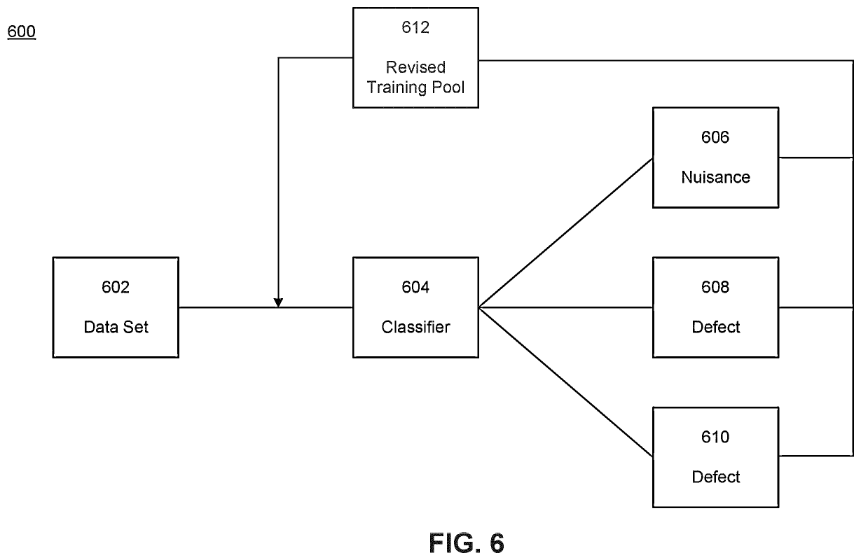

To improve the nuisance rate, a multi-phase system is used. FIG. 6 depicts a multi-phase classification tree 600 consistent with some embodiments of the present disclosure. Multi-phase classification tree 600 includes an image data set 602, an ADC classifier 604, a nuisance bin 606, defect bins 608 and 610, and a revised training pool 612. Classifier 604 may be, e.g., a C4 type classifier. The classification tree 600 is performed in a plurality of phases, where each phase uses better training data derived from the previous one. In phase I, image data set 602 is fed to ML-based ADC classifier 604. Classifier 604 sorts image data set 602 using multiple labeled training samples from different defect categories as an initial machine learning training pool. Candidates from image data set 602 are sorted into nuisance bin 606 and defect bins 608 and 610. After the first classification phase, the classification results are manually reviewed as discussed above with respect to FIG. 5B. Manual review identifies misclassifications from the first phase of the multiphase classification 600. However, information from the manual review is not simply used to determine a nuisance rate of the phase one classification. Instead, based on selected pattern features and defect strength thresholds, some misclassified defects from each type are re-labeled correctly and put into a revised training pool 612 for a second classification in phase II. The results of the phase II classification may again be subjected to manual review, and if desired, the review may be used to create another revised training pool 612. In this way several iterations can be performed, each with newly corrected training samples, until the classification results meet expectations. For example, classification may be repeated in phases until a nuisance rate reaches a predetermined level, or until a nuisance rate converges to a stable value. Alternatively, multi-phase classification may include a prescribed number of phases.

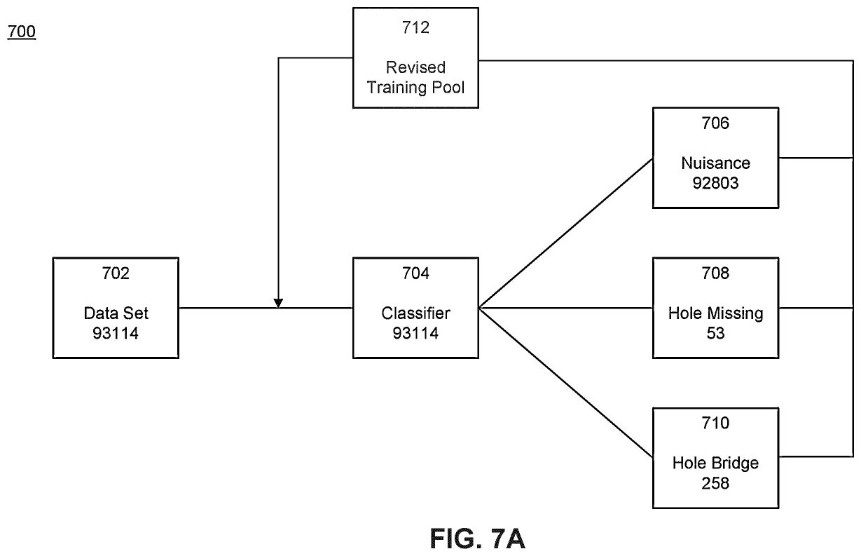

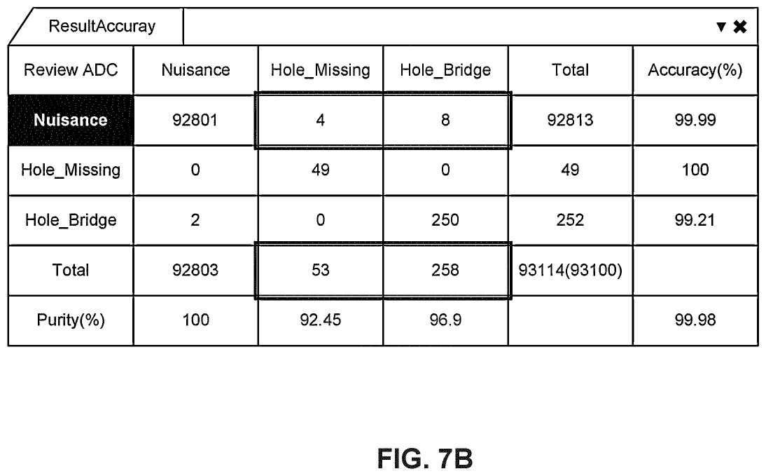

FIG. 7A shows an example case of a classification tree 700 with multi-phase training. Multi-phase classification tree 700 includes an image data set 702, an ADC classifier 704, a nuisance bin 706, a hole missing defect bin 708, a hole bridge defect bin 710, and a revised training pool 712. Classifier 704 may be, e.g., a C4 type classifier. The values shown in boxes 706, 708 and 710 represent the final binning results after a series of classification phases. As discussed above with respect to FIG. 6, these results are achieved after a plurality of classification phases in which classifier 704 sorts raw data 702 using the most recent iteration of a revised training pool 712. FIG. 7B depicts a result accuracy table for the classification tree of FIG. 7A. As discussed with respect to FIG. 5B above, the result accuracy table of FIG. 7B is a matrix created by comparing the ADC classification results to a manual review of the same data set 702. The multi-phase classification 700 provides a dramatic improvement to the nuisance rate over the single-phase example 500:

$$NR = ( 4 + 8 ) / ( 53 + 258 ) = 3.8 \%$$

However, feature sizes in IC manufacturing are always shrinking and the packing density of circuit features is constantly increasing. Therefore, a need exists to further reduce the nuisance rate NR to the greatest extent possible.

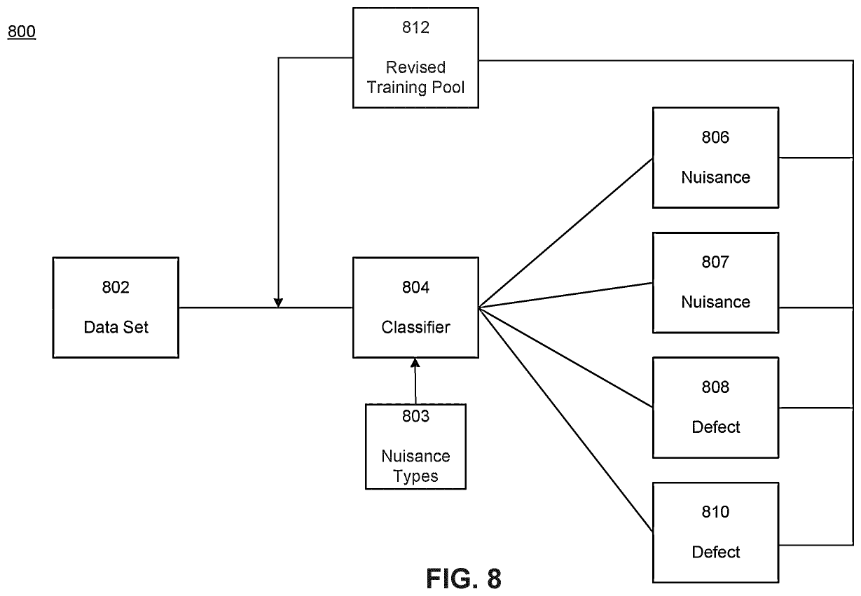

FIG. 8 shows a multi-phase multi-nuisance classification tree 800 according to some embodiments of the present disclosure. Multi-phase multi-nuisance classification tree 800 includes an image data set 802, a set of nuisance review types 803, an ADC classifier 804, nuisance bins 806 and 807, defect bins 808 and 810, and a revised training pool 812. Classifier 804 may be, e.g., a C4 type classifier. To further reduce the nuisance rate, classifier 804 of the present disclosure creates a plurality of nuisance bins 806 and 807 using a plurality of nuisance review types 803. Nuisance-type Information about the distinct nuisance types 803 is fed to classifier 804 before an initial classification phase begins. In some embodiments, the nuisance-type information may comprise a nuisance knowledge file analogous to a defect knowledge file as discussed above with respect to FIG. 3. In some embodiments, the nuisance-type information may comprise initial training samples corresponding to some or all of the nuisance types 806 and 807. The samples may be included in a first training pool for use in the first phase of a multi-phase classification process in the classification tree 800. When data set 802 is sorted by classifier 804, nuisances which may otherwise have been misclassified as a defect 808 or 810 may instead be classified as a particular nuisance type 806 or 807. For instance, the otherwise misclassified data may be classified as a particular nuisance type 807, while the remaining nuisances are classified as 806. It should be understood that the invention is not limited to two categories of defect review or nuisance review types.

After the first classification phase, the results are compared to results of a manual review. Based on different pattern features and strength thresholds, some misclassified defects and misclassified nuisances from each type are re-labeled correctly and put into a revised training pool 812 for a second training in phase II. Multiple iterations of this process can be performed until the training result meets expectations, similar to the process discussed above with respect to FIG. 7.

In some embodiments, a nuisance review type may be created based on its relationship or similarity to a defect review type. Stated another way, a nuisance review type may be designed to identify a candidate type that has the potential to be misclassified as a certain defect. Referring back to FIG. 5C, a defect review type “NOT hole missing” may be created to identify nuisances of the type 522, so that nuisances 522 are less likely to be misclassified as hole missing defect 521. Nuisances of the types 524, 525, and 527 may be used to create one or more “NOT hole bridge” nuisance types in order to avoid misclassification as hole bridge defects 523 or 525. In general, some embodiments are directed to nuisance review types that relate to a corresponding normal defect review type.

In some embodiments, nuisance review types are designed to break down the large data imbalance in classification categories. When a classifier lumps all nuisances into one type, the classification count in that category is much higher than the counts in any other category. Referring back to FIG. 7A, a nuisance classification count of 92,803 in bin 706 dwarfs the numbers shown in the defect bins 708 and 710. Such an imbalance can create problems for ML algorithms having optimization methods that are built on the assumption that data will be sorted into the different categories with somewhat equal numbers. When a real-world data set strays too far from this assumption, the classification accuracy may suffer. Many ML classifiers work best when the data counts in each category are more or less equal to one another. Learning algorithms tend to become less accurate in identifying data that belongs to smaller count categories. This is especially problematic when the data in the small bins are of greatest interest. For SEM inspection as shown in the examples above, classifiers can sift through large amounts of data in search of relatively few actual defects.

To counteract this problem, a plurality of nuisance review types may be created for the purpose of smoothing out the data imbalance. These nuisance review types may not be based on any similarity to particular defect review types, but instead can be designed with the goal of breaking down the large nuisance count into a plurality of smaller ones. In some embodiments, the plurality of nuisance review types may result in a plurality of bins having somewhat similar counts. For example, the largest and smallest counts of a plurality of nuisance types may be within ten times of each other. In some embodiments, the plurality of nuisance review types may be designed such that the largest classification count in a nuisance type can be within a multiple (e.g., 5×) of the smallest classification count.

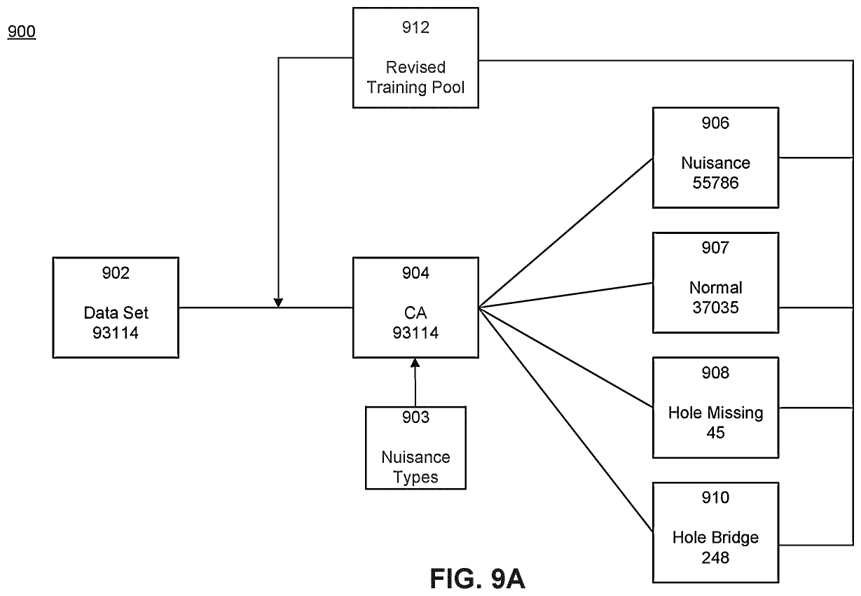

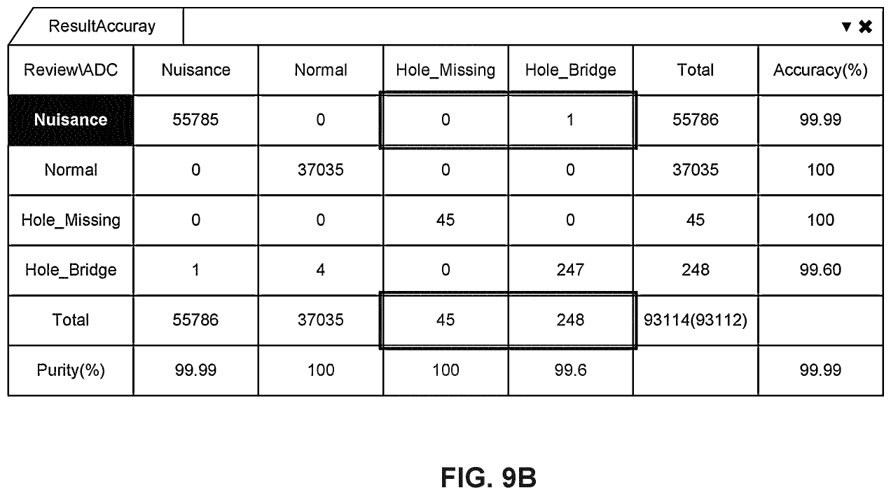

FIG. 9A shows an example case of a classification tree 900 with multi-phase multi-nuisance training according to some embodiments of the present disclosure. Multi-phase classification tree 900 includes an image data set 902, a set of nuisance review types 903, an ADC classifier 904, nuisance bins 906 and 907, defect bins 908 and 910, and a revised training pool 912. The values shown in boxes 906, 907, 908 and 910 represent the final binning results after a series of classification phases. As discussed above with respect to FIG. 7, these results are achieved after a plurality of classification phases in which classifier 904 sorts raw data 902 using the most recent iteration of revised training pool 912. To further reduce the nuisance rate, classifier 904 of the present disclosure creates a plurality of nuisance bins 906 and 907 using a plurality of nuisance review types. Nuisance-type information about the distinct nuisance types 903 is fed to classifier 904 before the initial classification phase begins. In the present embodiment, by way of example only, the classifier uses two nuisance review types to break the single nuisance category into two bins “Nuisance” and “Normal.” The former count of 92,803 is now broken into somewhat equal parts. FIG. 9B shows that the multi-phase classification 900 further reduces the nuisance rate over the single-nuisance example 700:

$$NR = ( 1 + 0 ) / ( 45 + 248 ) = 0.3 \%$$

Embodiments of the present disclosure can greatly reduce a nuisance rate in a defect inspection process. By more effectively filtering nuisances out of detection data, embodiments of the present disclosure may more accurately identify and compensate actual defects, leading to increased accuracy and higher yield in a device manufacturing process.

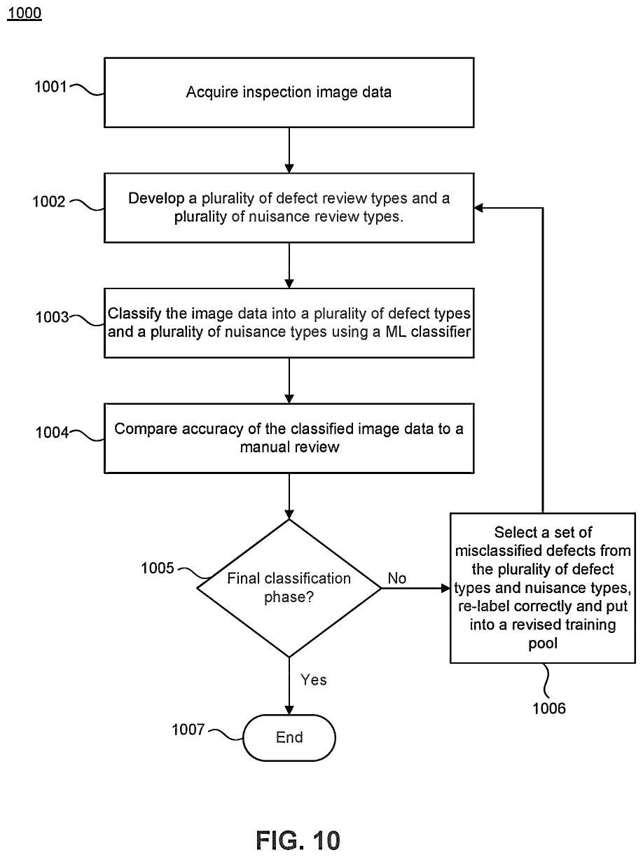

FIG. 10 shows an example method 1000 for improving a nuisance rate in image inspection data according to some embodiments of the present disclosure. In some embodiments, one or more steps of method 1000 may be performed by EBI system 100 of FIG. 1, a processor associated with EBI system 100 such as processor 109, and a multi-phase multi-nuisance classification tree 800 according to FIG. 8. One or more steps, not illustrated in FIG. 10, may be added, deleted, edited, or ordered differently, as appropriate.

At step 1001, an inspection tool such as a SEM acquires a set of image data. The image data includes a set of candidate defects to be classified by a ML classifier. The inspection tool may be, e.g., a tool 104 as discussed above with respect to FIGS. 1 & 2.

Steps 1002-1007 illustrate a multi-phase multi-nuisance classification method according to some embodiments of the present disclosure. The method may be carried out according to, e.g., the multi-phase multi-nuisance classification 800 of FIG. 8.

At step 1002, a plurality of defect review types and a plurality of nuisance review types are developed. In some embodiments, a defect review type may be designed to identify a particular defect type by comparison to a plurality of parameters in a knowledge file for the defect type stored in, e.g., storage 334 of FIG. 3. Parameters may include, e.g., size, edge roughness, depth, height, or any measurable feature parameter. The knowledge file may be developed using a set of training data for the defect review type. In some embodiments, a nuisance review type may be designed to identify a particular nuisance type by comparison to a plurality of parameters in a knowledge file for the nuisance type stored in, e.g., storage 334 of FIG. 3. Parameters may include, e.g., size, edge roughness, depth, height, or any measurable feature parameter. The knowledge file may be developed using a set of training data for the nuisance review type. In some embodiments a nuisance review type may be designed so as to break up nuisance types into a plurality of groups to reduce a data imbalance in a classification process.

At step 1003, a machine learning ADC classifier classifies the image data into a plurality of defect types based on the plurality of defect review types and a plurality of nuisance types based on the plurality of nuisance review types. The machine learning classifier may be, e.g., classifier 804 of FIG. 8. The machine learning classifier may be, e.g., a C4 classifier.

At step 1004, the classified image data is compared to a manual review of the image data. The manual review is a more rigorous and labor-intensive analysis to determine with higher confidence the actual nature of each candidate in the set. An operator can then compare the binning of each candidate under ADC to the actual result as determined by review. The comparison may be used to evaluate accuracy of the classification step 1003. For example, the comparison may evaluate accuracy by determining a nuisance rate NR as described above.

At 1005, it is determined whether the most recent phase of the multi-phase multi-nuisance classification is the final phase. The determination may be based on whether the evaluated accuracy, such as a nuisance rate NR, is within prescribed specifications. The determination may be based on whether the evaluated accuracy, such as a nuisance rate NR, has a value within a prescribed proximity to a previous value in a prior classification phase. Alternatively or additionally, the most recent phase may be determined to be a final phase based on a prescribed number of classification phases. If the most recent phase of the multi-phase multi-nuisance classification is determined to be a final phase, then the process moves to step 1006. A selection of misclassified candidates are re-labeled correctly and put into a revised training pool. The revised training pool may include new defect training data or new nuisance training data. The revised training pool may be used for further training in an additional phase beginning at step 1002. If the most recent phase of the multi-phase multi-nuisance classification is determined to be a final phase, the multi-phase classification ends at step 1007. The classified image data may then be used to improve a process, e.g., an integrated circuit or other semiconductor manufacturing process.

A non-transitory computer readable medium may be provided that stores instructions for a processor of controller 109 to carry out charged particle beam inspection, running a classifier network, performing pattern grouping, or other functions and methods consistent with the present disclosure such as method 1000. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The embodiments may further be described using the following clauses:
1. A method for improving a nuisance rate in image inspection data, the method comprising:
obtaining image data comprising a set of candidate defects;
developing a plurality of defect review types and a plurality of nuisance review types;
classifying the set of candidate defects into one or more defect types based on the plurality of defect review types during a first classification phase;
classifying the set of candidate defects into a plurality of nuisance types based on the plurality of nuisance review types during the first classification phase, and applying a machine learning based multi-phase classification to the classified set of candidate defects.
2. The method of clause 1, wherein the machine learning based multi-phase classification further comprises:
performing a review of the classified set of candidate defects from the first classification phase;
selecting at least one of a misclassified defect and a misclassified nuisance from the classified set of candidate defects;
re-labeling the at least one of the misclassified defect and the misclassified nuisance according to the review to create relabeled image data comprising the set of candidate defects;
adding the relabeled image data to a training pool of the machine learning based multi-phase classification to create a revised training pool; and
performing a second classification phase using the revised training pool.
3. The method of clause 1, wherein at least one of the plurality of nuisance review types is developed based on a defect review type.
4. The method of clause 1, wherein at least one of the plurality of nuisance review types is developed to reduce a data imbalance in the classified image data.
5. The method of clause 4, wherein the at least one of the plurality of nuisance review types includes
a first nuisance review type and a second nuisance review type; and
the first nuisance review type is developed to yield a classification count that is not more than 5 times
the classification count of the second nuisance review type.
6. The method of clause 1, wherein the set of candidate defects is from a charged particle beam apparatus including a detector.
7. The method of clause 6, wherein the charged particle beam apparatus including a detector is a scanning electron microscope (SEM).
8. A system for improving a nuisance rate in image inspection data, comprising:
a charged particle beam apparatus including a detector;
an image acquirer that includes circuitry to receive a detection signal from the detector and construct an image including a first feature; and
a controller with at least one processor and a non-transitory computer readable medium comprising instructions that, when executed by the at least one processor, cause the system to:
obtain image data comprising a set of candidate defects;
develop a plurality of defect review types and a plurality of nuisance review types;
classify the set of candidate defects into one or more defect types based on the plurality of defect review types during a first classification phase;
classify the set of candidate defects into a plurality of nuisance types based on the plurality of nuisance review types during the first classification phase, and
apply a machine learning based multi-phase classification to the classified set of candidate defects.
9. The system of clause 8, wherein the machine learning based multi-phase classification includes operations comprising:
perform a review of the classified set of candidate defects from the first classification phase;
selecting at least one of a misclassified defect and a misclassified nuisance from the classified set of candidate defects;
re-label the at least one of the misclassified defect and the misclassified nuisance according to the review to create relabeled image data comprising the set of candidate defects;
add the relabeled image data to a training pool of the machine learning based multi-phase classification to create a revised training pool; and
perform a second classification phase using the revised training pool.
10. The system of clause 8, wherein at least one of the plurality of nuisance review types is developed based on a defect review type.
11. The system of clause 8, wherein at least one of the plurality of nuisance review types is developed to reduce a data imbalance in the classified image data.
12. The system of clause 11, wherein the at least one of the plurality of nuisance review types includes
a first nuisance review type and a second nuisance review type; and
the first nuisance review type is developed to yield a classification count that is not more than 5 times the classification count of the second nuisance review type.
13. The system of clause 8, wherein the charged particle beam apparatus including a detector is a scanning electron microscope (SEM).
14. A non-transitory computer readable medium storing a set of instructions that is executable by one or more processors of a system to cause the system to perform a method comprising:
obtaining image data comprising a set of candidate defects;
developing a plurality of defect review types and a plurality of nuisance review types;
classifying the set of candidate defects into one or more defect types based on the plurality of defect review types during a first classification phase;
classifying the set of candidate defects into a plurality of nuisance types based on the plurality of nuisance review types during the first classification phase, and
applying a machine learning based multi-phase classification to the classified set of candidate defects.
15. The non-transitory computer readable medium of clause 14, wherein the machine learning based multi-phase classification further comprises:
performing a review of the classified set of candidate defects from the first classification phase;
selecting at least one of a misclassified defect and a misclassified nuisance from the classified set of candidate defects;
re-labeling the at least one of the misclassified defect and the misclassified nuisance according to the review to create relabeled image data comprising the set of candidate defects;
adding the relabeled image data to a training pool of the machine learning based multi-phase classification to create a revised training pool; and
performing a second classification phase using the revised training pool.
16. The non-transitory computer readable medium of clause 14, wherein at least one of the plurality of nuisance review types is developed based on a defect review type.
17. The non-transitory computer readable medium of clause 14, wherein at least one of the plurality of nuisance review types is developed to reduce a data imbalance in the classified image data.
18. The non-transitory computer readable medium of clause 17, wherein the at least one of the plurality of nuisance review types includes a first nuisance review type and a second nuisance review type; and
the first nuisance review type is developed to yield a classification count that is not more than 5 times the classification count of the second nuisance review type.
19. The non-transitory computer readable medium of clause 14, wherein the obtained image data is from a charged particle beam apparatus including a detector.
20. The non-transitory computer readable medium of clause 19, wherein the charged particle beam apparatus including a detector is a scanning electron microscope (SEM).
21. A method for improving a nuisance rate in image inspection data, the method comprising: obtaining image data comprising a set of candidate defects;
developing one or more first defect review types;
classifying the set of candidate defects into a nuisance type and one or more defect types based on the one or more first defect review types a during a first machine learning based classification phase;
performing a manual review of the classified set of candidate defects to determine an actual classification of the image data,
creating a comparison of a result of the first machine learning based classification phase to a result of the manual review;
creating a set of revised training data based on the comparison;
developing one or more second defect review types using the revised training data, the second defect review types being different from the first defect review types; and
reclassifying the set of candidate defects into the nuisance type and one or more defect types based on the one or more second defect review types during a second machine learning based classification phase.
22. The method of clause 21, wherein the classifying the set of candidate defects into a nuisance type includes classifying the set of candidate defects into a plurality of nuisance types.
23. The method of clause 22, wherein at least one of the plurality of nuisance review types is developed based on a defect review type.
24. The method of clause 22, wherein at least one of the plurality of nuisance review types is developed to reduce a data imbalance in the classified image data.
25. The method of clause 24, wherein the at least one of the plurality of nuisance review types includes a first nuisance review type and a second nuisance review type; and
the first nuisance review type is developed to yield a classification count that is not more than 5 times
the classification count of the second nuisance review type.
26. The method of clause 21, wherein the obtained image data is from a charged particle beam apparatus including a detector.
27. The method of clause 21, wherein the charged particle beam apparatus including a detector is a scanning electron microscope (SEM).
28. The method of clause 21, further comprising creating a comparison of a result of the second machine learning based classification phase to a result of the manual review;
creating a set of second revised training data based on the comparison;
developing one or more third defect review types using the revised training data, the third defect review types being different from the first defect review types and the defect review types; and
reclassifying the set of candidate defects into the nuisance type and one or more defect types based on the one or more third defect review types during a third machine learning based classification phase.
29. A method for improving a nuisance rate in image inspection data, the method comprising: obtaining image data comprising a set of candidate defects;
developing a plurality of nuisance review types;
classifying the set of candidate defects into a plurality of nuisance types based on the plurality of nuisance review types during a first classification phase, and
applying a machine learning based multi-phase classification to the classified set of candidate defects.
30. The method of clause 29, wherein the machine learning based multi-phase classification further comprises:
performing a review of the classified set of candidate defects from the first classification phase;
selecting a misclassified nuisance from the classified set of candidate defects;
re-labeling the misclassified nuisance according to the review to create relabeled image data comprising the set of candidate defects;
adding the relabeled image data to a training pool of the machine learning based multi-phase classification to create a revised training pool; and
performing a second classification phase using the revised training pool.
31. The method of clause 29, further comprising developing a defect review type.
32. The method of clause 31, wherein at least one of the plurality of nuisance review types is developed based on the defect review type.
33. The method of clause 31, further comprising developing a plurality of defect review types.
34. The method of clause 29, wherein at least one of the plurality of nuisance review types is developed to reduce a data imbalance in the classified image data.
35. The method of clause 34, wherein the at least one of the plurality of nuisance review types includes a first nuisance review type and a second nuisance review type; and
the first nuisance review type is developed to yield a classification count that is not more than 5 times
the classification count of the second nuisance review type.
36. The method of clause 29 wherein the set of candidate defects is from a charged particle beam apparatus including a detector.
37. The method of clause 36, wherein the charged particle beam apparatus including a detector is a scanning electron microscope (SEM).
38. A non-transitory computer readable medium storing a set of instructions that is executable by one or more processors of a system to cause the system to perform a method comprising:
obtaining image data comprising a set of candidate defects;
developing one or more first defect review types;
classifying the set of candidate defects into a nuisance type and one or more defect types based on the one or more first defect review types a during a first machine learning based classification phase;
performing a manual review of the classified set of candidate defects to determine an actual classification of the image data,
creating a comparison of a result of the first machine learning based classification phase to a result of the manual review;
creating a set of revised training data based on the comparison;
developing one or more second defect review types using the revised training data, the second defect review types being different from the first defect review types; and
reclassifying the set of candidate defects into the nuisance type and one or more defect types based on the one or more second defect review types during a second machine learning based classification phase.
39. The non-transitory computer readable medium of clause 38, wherein the classifying the set of candidate defects into a nuisance type includes classifying the set of candidate defects into a plurality of nuisance types.
40. The non-transitory computer readable medium of clause 39, wherein at least one of the plurality of nuisance review types is developed based on a defect review type.
41. The non-transitory computer readable medium of clause 39, wherein at least one of the plurality of nuisance review types is developed to reduce a data imbalance in the classified image data.
42. The non-transitory computer readable medium of clause 41, wherein the at least one of the plurality of nuisance review types includes a first nuisance review type and a second nuisance review type; and the first nuisance review type is developed to yield a classification count that is not more than 5 times the classification count of the second nuisance review type.
43. The non-transitory computer readable medium of clause 38, wherein the obtained image data is from a charged particle beam apparatus including a detector.
44. The non-transitory computer readable medium of clause 38, wherein the charged particle beam apparatus including a detector is a scanning electron microscope (SEM).
45. The non-transitory computer readable medium of clause 38, wherein the set of instructions is executable by one or more processors of the system to cause the system to further perform: creating a comparison of a result of the second machine learning based classification phase to a result of the manual review;
creating a set of second revised training data based on the comparison;
developing one or more third defect review types using the revised training data, the third defect review types being different from the first defect review types and the defect review types; and
reclassifying the set of candidate defects into the nuisance type and one or more defect types based on the one or more third defect review types during a third machine learning based classification phase.
46. A non-transitory computer readable medium storing a set of instructions that is executable by one or more processors of a system to cause the system to perform a method comprising:
obtaining image data comprising a set of candidate defects;
developing a plurality of nuisance review types;
classifying the set of candidate defects into a plurality of nuisance types based on the plurality of nuisance review types during a first classification phase, and applying a machine learning based multi-phase classification to the classified set of candidate defects.
47. The non-transitory computer readable medium of clause 46, wherein the machine learning based multi-phase classification further comprises:
performing a review of the classified set of candidate defects from the first classification phase;
selecting a misclassified nuisance from the classified set of candidate defects;
re-labeling the misclassified nuisance according to the review to create relabeled image data comprising the set of candidate defects;
adding the relabeled image data to a training pool of the machine learning based multi-phase classification to create a revised training pool; and
performing a second classification phase using the revised training pool.
48. The non-transitory computer readable medium of clause 46, wherein the set of instructions is executable by one or more processors of the system to cause the system to further perform:
developing a defect review type.
49. The non-transitory computer readable medium of clause 48, wherein at least one of the plurality of nuisance review types is developed based on the defect review type.
50. The non-transitory computer readable medium of clause 48, wherein the set of instructions is executable by one or more processors of the system to cause the system to further perform: developing a plurality of defect review types.
51. The non-transitory computer readable medium of clause 46, wherein at least one of the plurality of nuisance review types is developed to reduce a data imbalance in the classified image data.
52. The non-transitory computer readable medium of clause 51, wherein the at least one of the plurality of nuisance review types includes a first nuisance review type and a second nuisance review type; and
the first nuisance review type is developed to yield a classification count that is not more than 5 times the classification count of the second nuisance review type.
53. The non-transitory computer readable medium of clause 46, wherein the set of candidate defects is from a charged particle beam apparatus including a detector.
54. The non-transitory computer readable medium of clause 53, wherein the charged particle beam apparatus including a detector is a scanning electron microscope (SEM).
55. A system for improving a nuisance rate in image inspection data, comprising:
a charged particle beam apparatus including a detector;
an image acquirer that includes circuitry to receive a detection signal from the detector and construct an image including a first feature; and
a controller with at least one processor and a non-transitory computer readable medium comprising instructions that, when executed by the at least one processor, cause the system to:
obtain image data comprising a set of candidate defects;
develop a plurality of nuisance review types;
classify the set of candidate defects into a plurality of nuisance types based on the plurality of nuisance review types during a first classification phase, and
apply a machine learning based multi-phase classification to the classified set of candidate defects.
56. The system of clause 55, wherein the machine learning based multi-phase classification includes operations comprising:
perform a review of the classified set of candidate defects from the first classification phase; select a misclassified nuisance from the classified set of candidate defects;
re-label the misclassified nuisance according to the review to create relabeled image data comprising the set of candidate defects;
add the relabeled image data to a training pool of the machine learning based.
57. The system of clause 55, wherein the controller with the at least one processor and the non-transitory computer readable medium comprising instructions that, when executed by the at least one processor, cause the system to perform:
developing a defect review type.
58. The system of clause 55, wherein at least one of the plurality of nuisance review types is developed based on the defect review type.
59. The system of clause 58, wherein the controller with the at least one processor and the non-transitory computer readable medium comprising instructions that, when executed by the at least one processor, cause the system to perform:
developing a plurality of defect review types.
60. The system of clause 55, wherein at least one of the plurality of nuisance review types is developed to reduce a data imbalance in the classified image data.
61. The system of clause 55, wherein the at least one of the plurality of nuisance review types includes a first nuisance review type and a second nuisance review type; and
the first nuisance review type is developed to yield a classification count that is not more than 5 times the classification count of the second nuisance review type.
62. The system of clause 55, wherein the set of candidate defects is from a charged particle beam apparatus including a detector.
63. The system of clause 62, wherein the charged particle beam apparatus including a detector is a scanning electron microscope (SEM).
64. A system for improving a nuisance rate in image inspection data, comprising:
a charged particle beam apparatus including a detector;
an image acquirer that includes circuitry to receive a detection signal from the detector and construct an image including a first feature; and
a controller with at least one processor and a non-transitory computer readable medium comprising instructions that, when executed by the at least one processor, cause the system to perform a method comprising:
obtain image data comprising a set of candidate defects;
develop one or more first defect review types;
classify the set of candidate defects into a nuisance type and one or more defect types based on the one or more first defect review types a during a first machine learning based classification phase; perform a manual review of the classified set of candidate defects to determine an actual classification of the image data,
create a comparison of a result of the first machine learning based classification phase to a result of the manual review;
create a set of revised training data based on the comparison;
develop one or more second defect review types using the revised training data, the second defect review types being different from the first defect review types; and
reclassify the set of candidate defects into the nuisance type and one or more defect types based on the one or more second defect review types during a second machine learning based classification phase.
65. The system of clause 64, wherein the classifying of the set of candidate defects into a nuisance type includes a classifying of the set of candidate defects into a plurality of nuisance types.
66. The system of clause 65, wherein at least one of the plurality of nuisance review types is developed based on a defect review type.
67. The system of clause 65, wherein at least one of the plurality of nuisance review types is developed to reduce a data imbalance in the classified image data.
68. The system of clause 67, wherein the at least one of the plurality of nuisance review types includes a first nuisance review type and a second nuisance review type; and the first nuisance review type is developed to yield a classification count that is not more than 5 times the classification count of the second nuisance review type.
69. The system of clause 64, wherein the obtained image data is from a charged particle beam apparatus including a detector.
70. The system of clause 64, wherein the charged particle beam apparatus including a detector is a scanning electron microscope (SEM).
71. The system of clause 64, wherein the controller with the at least one processor and the non-transitory computer readable medium comprising instructions that, when executed by the at least one processor, cause the system to perform:
create a comparison of a result of the second machine learning based classification phase to a result of the manual review;
create a set of second revised training data based on the comparison;
develop one or more third defect review types using the revised training data, the third defect review types being different from the first defect review types and the defect review types; and
reclassify the set of candidate defects into the nuisance type and one or more defect types based on the one or more third defect review types during a third machine learning based classification phase.

The block diagrams in the figures illustrate the architecture, functionality, and operation of possible implementations of systems, methods, and computer hardware/software products according to various exemplary embodiments of the present disclosure. In this regard, each block in a schematic diagram may represent certain arithmetical or logical operation processing that may be implemented using hardware such as an electronic circuit. Blocks may also represent a module, a segment, or a portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted.

It should also be understood that each block of the block diagrams, and combination of the blocks, may be implemented by special purpose hardware-based systems that perform the specified functions or acts, or by combinations of special purpose hardware and computer instructions.

While the present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method for improving a nuisance rate in image inspection data, the method comprising:
obtaining image data comprising a set of candidate defects;
developing a plurality of defect review types and a plurality of nuisance review types;
classifying the set of candidate defects into one or more defect types based on the plurality of defect review types during a first classification phase;
classifying the set of candidate defects into a plurality of nuisance types based on the plurality of nuisance review types during the first classification phase, and
applying a machine learning based multi-phase classification to the classified set of candidate defects.

2. The method of claim 1, wherein the machine learning based multi-phase classification further comprises:
performing a review of the classified set of candidate defects from the first classification phase;
selecting at least one of a misclassified defect and a misclassified nuisance from the classified set of candidate defects;
re-labeling the at least one of the misclassified defect and the misclassified nuisance according to the review to create relabeled image data comprising the set of candidate defects;
adding the relabeled image data to a training pool of the machine learning based multi-phase classification to create a revised training pool; and
performing a second classification phase using the revised training pool.

3. The method of claim 1, wherein at least one of the plurality of nuisance review types is developed based on a defect review type.

4. The method of claim 1, wherein at least one of the plurality of nuisance review types is developed to reduce a data imbalance in the classified set of candidate defects.

5. The method of claim 4, wherein the at least one of the plurality of nuisance review types includes a first nuisance review type and a second nuisance review type; and
the first nuisance review type is developed to yield a classification count that is not more than 5 times the classification count of the second nuisance review type.

6. The method of claim 1, wherein the set of candidate defects is from a charged particle beam apparatus including a detector.

7. The method of claim 6, wherein the charged particle beam apparatus including a detector is a scanning electron microscope (SEM).

8. A system for improving a nuisance rate in image inspection data, comprising:
a charged particle beam apparatus including a detector;
an image acquirer that includes circuitry to receive a detection signal from the detector and construct an image including a first feature; and
a controller with at least one processor and a non-transitory computer readable medium comprising instructions that, when executed by the at least one processor, cause the system to:
obtain image data comprising a set of candidate defects;
develop a plurality of defect review types and a plurality of nuisance review types;
classify the set of candidate defects into one or more defect types based on the plurality of defect review types during a first classification phase;
classify the set of candidate defects into a plurality of nuisance types based on the plurality of nuisance review types during the first classification phase, and
apply a machine learning based multi-phase classification to the classified set of candidate defects.

9. The system of claim 8, wherein the machine learning based multi-phase classification includes operations comprising:
perform a review of the classified set of candidate defects from the first classification phase;
select at least one of a misclassified defect and a misclassified nuisance from the classified set of candidate defects;
re-label the at least one of the misclassified defect and the misclassified nuisance according to the review to create relabeled image data comprising the set of candidate defects;
add the relabeled image data to a training pool of the machine learning based multi-phase classification to create a revised training pool; and
perform a second classification phase using the revised training pool.

10. The system of claim 8, wherein at least one of the plurality of nuisance review types is developed based on a defect review type.

11. The system of claim 8, wherein
at least one of the plurality of nuisance review types is developed to reduce a data imbalance in the classified set of candidate defects.

12. The system of claim 11, wherein the at least one of the plurality of nuisance review types includes a first nuisance review type and a second nuisance review type; and
the first nuisance review type is developed to yield a classification count that is not more than 5 times the classification count of the second nuisance review type.

13. The system of claim 8, wherein the charged particle beam apparatus including a detector is a scanning electron microscope (SEM).

14. A non-transitory computer readable medium storing a set of instructions that is executable by one or more processors of a system to cause the system to perform a method comprising:
obtaining image data comprising a set of candidate defects;
developing a plurality of defect review types and a plurality of nuisance review types;
classifying the set of candidate defects into one or more defect types based on the plurality of defect review types during a first classification phase;
classifying the set of candidate defects into a plurality of nuisance types based on the plurality of nuisance review types during the first classification phase, and
applying a machine learning based multi-phase classification to the classified set of candidate defects.

15. The non-transitory computer readable medium of claim 14, wherein the machine learning based multi-phase classification further comprises:
performing a review of the classified set of candidate defects from the first classification phase;
selecting at least one of a misclassified defect and a misclassified nuisance from the classified set of candidate defects;
re-labeling the at least one of the misclassified defect and the misclassified nuisance according to the review to create relabeled image data comprising the set of candidate defects;
adding the relabeled image data to a training pool of the machine learning based multi-phase classification to create a revised training pool; and
performing a second classification phase using the revised training pool.

16. The non-transitory computer readable medium of claim 14, wherein at least one of the plurality of nuisance review types is developed based on a defect review type.

17. The non-transitory computer readable medium of claim 14, wherein at least one of the plurality of nuisance review types is developed to reduce a data imbalance in the classified set of candidate defects.

18. The non-transitory computer readable medium of claim 17, wherein the at least one of the plurality of nuisance review types includes a first nuisance review type and a second nuisance review type; and the first nuisance review type is developed to yield a classification count that is not more than 5 times the classification count of the second nuisance review type.

19. The non-transitory computer readable medium of claim 14, wherein the obtained image data is from a charged particle beam apparatus including a detector.

20. The non-transitory computer readable medium of claim 19, wherein the charged particle beam apparatus including a detector is a scanning electron microscope (SEM).
